(19) United States
(12) Patent Application Publication
(10) Pub. No.: US 2025/0299905 A1
(43) Pub. Date: Sep. 25, 2025

(54) MULTI-BEAM CHARGED PARTICLE MICROSCOPE DESIGN WITH DETECTION SYSTEM FOR FAST CHARGE COMPENSATION

(71) Applicant: Carl Zeiss MultiSEM GmbH, Oberkochen (DE)

(72) Inventors: Dirk ZEIDLER, Oberkochen (DE); Bjoern MIKSCH, Heidenheim (DE); Markus KOCH, Neu-Ulm (DE); Thomas SCHMID, Aalen (DE); Felix MENKE, Oberkochen (DE); Thomas DIETERLE, Murrhardt (DE)

(21) Appl. No.: 19/233,358

(22) Filed: Jun. 10, 2025

Related U.S. Application Data
(63) Continuation of application No. PCT/EP2023/025501, filed on Nov. 28, 2023.

(30) Foreign Application Priority Data
Dec. 16, 2022 (DE) 10 2022 213 751.5

(51) Int. Cl. H01J 37/145; H01J 37/06

(52) U.S. Cl. CPC H01J 37/145; H01J 37/06

(57) ABSTRACT

A multi-beam charged particle beam system with a secondary electron imaging system is configured to dynamically compensate charging effects of a sample over a large range of landing energies of primary charged particles. The multi-beam charged particle beam system has reduced complexity and comprises a fast electrostatic lens element and a mechanism for compensating charging effects. The mechanism can be a second fast electrostatic lens element or a position actuator. The technology can used in wafer inspection with multi-beam charged particle beam system.

### CROSS-REFERENCE TO RELATED APPLICATIONS

The present application is a continuation of, and claims benefit under 35 USC 120 to, international application No. PCT/EP2023/025501, filed Nov. 28, 2023, which claims benefit under 35 USC 119 of German Application No. 10 2022 213 751.5, filed Dec. 16, 2022. The entire disclosure of each of these applications is incorporated by reference herein.

### FIELD

The disclosure relates to a multi-beam charged particle microscope with improved imaging contrast and a method for inspecting semiconductor features with improved image contrast.

### BACKGROUND

WO 2005/024881 A2 discloses an electron microscope system which operates with a multiplicity of electron beamlets for the parallel scanning of an object to be inspected with a bundle of electron beamlets. The bundle of primary charged particle beamlets is generated by directing a primary charged particle beam onto a multi-beam forming unit, comprising at least one multi-aperture plate, which has a multiplicity of openings. One portion of the electrons of the electron beam is incident onto the multi-aperture plate and is absorbed there, and another portion of the beam transmits the openings of the multi-aperture plate and thereby in the beam path downstream of each opening an electron beamlet is formed whose cross section is defined by the cross section of the opening. The primary charged particle beamlets are focused by an objective lens on a surface of a sample and trigger secondary electrons or backscattered electrons to emanate as secondary electron beamlets from the sample, which are collected and imaged onto a detector. Each of the secondary beamlets is incident onto a separate detector element or group of detector elements, so that the secondary electron intensities detected therewith provide information relating to the surface of the sample at the location where the corresponding primary beamlet is incident onto the sample. The bundle of primary beamlets is scanned systematically over the surface of the sample and an electron microscopic image of the sample is generated in the usual way of scanning electron microscopes.

Generally, the imaging contrast of a scanning electron microscope generally depends on the signal generated by secondary electrons, which depends on the secondary electron (SE) yield per primary electron and a geometrical collection efficiency of the electron microscope. The SE yield depends on material characteristics and the kinetic energy of the primary electrons. The SE yield may further have an angular component, i.e. the SE yield can be a function of the polar angle with respect to a surface normal to the sample.

The secondary electron beamlets collected by the objective lens are then guided to a detector. The secondary electrons generated and extracted from the sample surface, however, are in many cases subject to charging effects at the sample surface, especially if the secondary electron yield is not in balance with the incident primary electron current. These charging effects can lead to a deterioration of the secondary electron beamlets and can lead to a reduced image contrast, an increase of cross-talk or even a complete loss of the secondary electron signal. Charging effects can become more and more deteriorating the image contrast in wafer inspection tasks during fabrication of integrated circuits. Such wafers comprise semiconductor materials, local capacities, and isolators, which may accumulate for example surface charges. In other examples, the target of an inspection task are wafers covered by photoresist, wherein photoresist accumulates local surface charges. Patent applications WO 2022/248141 A1 and DE 102022114923.4 disclose monitoring methods to detect charging effects at such charging samples. DE 102018124044 B3 proposes a deconvolution of cross-talk. However, a deconvolution is, in general, only possible for minor charging effects. Generally, for a compensation of charging effects during the imaging of secondary electron beamlets, an electron-optical mechanism is used to maintain a high contrast at a secondary electron detector.

Different mechanisms have been proposed to improve an imaging contrast of a multi-beam electron microscope in presence of charging effects. U.S. Pat. Nos. 11,049,686, 10,896,800, 10,811,215 and WO 2021/239380 A1 propose an arrangement of several active electrostatic or magneto-dynamic elements within a secondary electron imaging system. However, these systems might be high complexity, or might not allow a fast correction of deteriorated secondary electron beamlets with sufficient magnitude of correction. For example, U.S. Pat. No. 10,811,215 proposes a secondary electron imaging system designs of relatively high complexity, comprising up to nine electro-optical lenses.

Generally, elements for focus adjustment, image magnification and image rotation within a secondary electron imaging system are well known. For example, U.S. Pat. Nos. 9,368,314, 7,601,972, 7,049,585, 6,992,290, US 2009/014649, or U.S. Pat. No. 8,362,425, mention zoom lenses and rotation compensators in secondary electron imaging systems, or provide simplified sketches of secondary electron imaging systems, like for example in US 2016/0268096. However, the examples of these references generally do not provide more than a raw conception of a secondary electron imaging system, which is not reduced to a practical design. Therefore, there is still a desire for a secondary imaging system of a multi-beam electron beam system which offers a high speed and large range for the compensation of charging effects.

US 2022/0108864 A1 discloses inter alia an arrangement of additional electrostatic deflectors, electrostatic stigmators and electrostatic lenses for fast correction purposes in a secondary electron-optical beam path. DE 102020125534 B3 and DE102021105201 A1 disclose a multiple particle beam microscope and an associated method with a fast autofocus around an adjustable working distance. Proposed is a system having one or more fast autofocus correction lenses for adapting, in high-frequency fashion, the focusing, the position, the landing angle and the rotation of individual particle beams upon incidence on a wafer surface during the wafer inspection. Fast autofocusing in the secondary path of the particle beam system can be implemented in analogous fashion. An additional increase in precision can be attained using a fast aberration correction mechanism in the form of deflectors and/or stigmators.

International patent application No. PCT/EP2023/025443 (published as WO 2024/099587A1) proposes an optimization of the landing energy of the primary electrons for a given material composition at a sample surface. Generally, with a variable landing energy, secondary electron yield can be optimized, or a charging of a sample can be reduced. With the change of the landing energy or primary electrons, however, also the energy of secondary electrons extracted from the sample surface can be changed. Therefore, there can be a desire to provide a secondary electron imaging system which provides a compensation mechanism for charging effects over a wide range of landing energies of primary electrons. Furthermore, the increasing demand for higher resolution of below 3 nanometers (nm), below 2 nm or even less are typically achieved by low landing energies with landing energies of primary electrons below 800 electron Volts (eV), for example below 500 eV, below 300 eV or even less. Therefore, it can be desirable to provide a secondary electron imaging system which provides a compensation mechanism for charging effects over a wide range of low landing energies of primary electrons.

### SUMMARY

The disclosure seeks to provide a multi-beam charged particle beam system and a method of operating a multi-beam charged particle beam system for image acquisition with a relatively high imaging contrast. The disclosure includes an improved imaging system design for the imaging of the secondary electron beamlets generated from charging samples.

In some embodiments, a multi-beam charged particle beam system according to the disclosure is configured for compensation of charging effects during a scanning image acquisition over a large range of different kinetic energies ES of secondary electrons. The kinetic energy ES of secondary electrons depend on a selection of a landing energy EL of primary charged particles at a sample surface, where the secondary electrons are generated. The secondary electrons are extracted and accelerated to a kinetic energy ES depending on the landing energy. In an example, the kinetic energy ES of secondary electrons is a high energy above for example 20 kiloelectron Volts (keV) or more, for example close to 30 keV. Therefore, the kinetic energy ES of secondary electrons changes by +/−1 keV, depending on a selected landing energy EL for performing an inspection task.

In an aspect, a multi-beam charged particle beam system according to the disclosure comprises a charged-particle multi-beamlet generator for generating a plurality of primary charged particle beamlets. The multi-beam charged particle beam system comprises an object irradiation unit, comprising a beam divider and an objective lens for forming a plurality of focus spots of primary charged particle beamlets in an object plane, in which a surface of a wafer is arranged by a sample stage. The multi-beam charged particle beam system further comprises a voltage supply unit configured to provide during use a sample voltage VS to a wafer for adjusting a selected landing energy EL of primary charged particles over a large range between 200 eV, or even 100 eV, and 2 keV. The multi-beam charged particle beam system further comprises a detection unit, configured for imaging the high energy secondary electrons on an image sensor. In an example, the detection unit is of reduced complexity and comprises only a first magneto-dynamic lens, a pair of magneto-dynamic lenses, and a first fast electrostatic lens element and a second mechanism, wherein the first fast electrostatic lens element and the second mechanism are configured for a dynamic compensation of charging effects during use over the large range of landing energies EL of primary charged particles.

In a first embodiment, a fast electrostatic lens element for quickly changing a lens power for an electron beam of high kinetic energy ES >20 keV, for example ES up to 30 keV is provided. The fast electrostatic lens element comprises at least a first electrode connected to a first, dynamic voltage supply unit, configured for providing during use a dynamically changing low voltage C below +/−500 Volts (V), such as below +/−250V. The fast electrostatic lens element further comprises at least a second electrode connected to a second, static voltage supply unit configured for providing during use a quasi-static high voltage V <−5 kiloVolts (kV), such as V <−8 kV or V ˜−10 kV. Thereby, a large lens power with a high, static offset voltage is achieved for the electron beam of high kinetic energy. With the reduction of dynamically changing voltage C to low voltages below +/−500 V, such as below +/−250V, it is possible to achieve a fast change of a lens power for dynamically changing a lens power during a scanning image acquisition. In an example, the first and the second electrode are identical electrodes and static high voltage V and dynamically varying low voltage C are combined by a voltage combiner.

In an example, the first and second electrodes are configured as an isolated tube lens segment arranged between a first tube segment and a second tube segment. The first and second tube segment may be on a same voltage, or for example set to ground level. An electrode can be arranged as isolated tube lens segment in an axial range of a yoke of a magnetic lens with a coil, configured for generating a magnetic lens field in the isolated tube lens segment. Thereby, a large lens power can be generated by the magnetic lens, and a dynamical change of the lens power can be achieved by providing a dynamically changing voltage C to the lens tube electrode. Furthermore, the fast electrostatic lens element can be configured with a large electrostatic lens power by adding a static offset voltage V with the second, static voltage supply unit.

In an example, the first electrode is placed between the second electrode and a third electrode, the third electrode being connected to the second, static voltage supply unit configured for providing during use a quasi-static high voltage V <−5 kV, such as V <−8 kV or V ˜−10 kV to the third electrode. In an example, the fast electrostatic lens element comprises five or more electrodes. With the fast electrostatic lens element, a plurality of high-energy secondary electron beamlets of a multi-beam charged particle beam system can be manipulated during a scanning image acquisition and charging effects of a sample during scanning image acquisition can be compensated.

In an example, the first fast electrostatic lens element is placed within a first tube segment and second tube segment of a beam tube enclosing a secondary electron beam path. In an example, the first fast electrostatic lens element comprises at least one electrode connected to a first, dynamic voltage supply unit, configured to provide during use a dynamically changing low voltage C of up to +/−200V to the at least one electrode. In an example, the first fast electrostatic lens element is arranged downstream of the first magneto-dynamic lens between a first, low energy intermediate image position and a second, high energy intermediate image position of the secondary electron beamlets. In an example, the first fast electrostatic lens element comprises five or more electrodes with at least two electrodes connected to a second, static voltage supply unit configured for providing during use of a quasi-static high voltage V larger than 5 keV, larger than 8 keV or even larger than 10 keV to each of the two electrodes.

In a second embodiment, the second mechanism is a second fast electrostatic lens element, similar to the first fast electrostatic lens element. The first and second fast electrostatic lens elements can be arranged downstream of the first magneto-dynamic lens between a first, low energy intermediate image position and a second, high energy intermediate image position of the secondary electron beamlets. The first, low energy intermediate image position and the second, high energy intermediate image position of the secondary electron beamlets can be determined according to the range of landing energies between for example 200 eV, or even 100 eV, and 2 keV.

In a third embodiment, the second mechanism is a position actuator configured for changing the axial position of the first fast electrostatic lens element. With a position actuator, it is possible to place or change the axial position of the first fast electrostatic lens between a first, low energy intermediate image position and a second, high energy intermediate image position of the secondary electron beamlets.

In a fourth embodiment, the second mechanism is formed as a hybrid lens configured for forming during use a quasi-static magnetic lens field at an axial position of an isolated tube lens segment between a first beam tube segment and a second beam tube segment. The tube lens segment can be connected to a first, dynamic voltage supply unit configured for dynamically changing a lens power of the hybrid lens. Thereby, a lens power of the hybrid lens can be dynamically changed, and a charging effect can be compensated during a scanning image acquisition. In an example, the hybrid lens comprises a coil and a yoke, configured for limiting the quasi-static magnetic field during use to the axial position of the isolated tube lens segment. With the embodiments, a fast compensation of charging effects can be compensated for different landing energies EL and thus different kinetic energies of high energy secondary electrons with a kinetic energy of up to 30 keV and a variation range of +/−1 keV.

In a fifth embodiment, the detection unit comprises a lateral or tilt manipulator, configured for adjusting a lateral position or tilt of a lens element of the secondary electron beam path. Thereby, a beam path of secondary electron beamlets can be adjusted without the need of quasi-static deflectors or multipole-elements. Thereby, a complexity of a detection unit for a multi-beam charged particle beam system according to the disclosure can be further reduced.

In a sixth embodiment, a method of operating a multi-beam charged particle beam system is disclosed. The method can be configured to compensate charging effects during secondary electron imaging with a multi-beam charged particle beam system, wherein the kinetic energy ES of secondary electrons is high and further depend on a selected landing energy of primary electrons of an inspection task. The method can comprise selecting an imaging setting including selection of a landing energy EL of primary charged particles. The method can comprise adjusting a deceleration field close to a wafer surface and at least one lens power of at least one magneto-dynamic projection lens of a detection unit to the selected landing energy EL. The method can further comprise starting of a scanning image acquisition and in parallel monitoring a position of a plurality of focus points a plurality of secondary electron beamlets during the scanning image acquisition. The method can comprise determining a change in the positions of the plurality of focus points and transferring the change in the positions into a compensation signal. The method can further comprise converting the compensation signal into at least one dynamically changing low voltage C and providing the at least one dynamically changing low voltage C to at least one first electrode of a fast electrostatic lens element of the detection unit.

In an example, the monitoring is performed at a frame rate of at least 30 frames per second, such as with more than 100 frames per second. In an example, the method further comprises, during the step of adjusting, providing at least one high, quasi-static voltage V to at least one second electrode of a fast lens element of the detection unit.

By the embodiments or examples of the disclosure, a multi-beam charged particle beam system and a method of operating a multi-beam charged particle beam system with improved image contrast is provided. The disclosure can allows wafer inspection, including charging wafer samples, with relatively high precision and with relatively high accuracy. It will be understood that the disclosure is not limited to the embodiments and examples but comprises also combinations and variations of the embodiments and examples.

### BRIEF DESCRIPTION OF THE DRAWINGS

Embodiments of the present disclosure will be explained in more detail with reference to drawings, in which:

FIG. 1 is a schematic sectional view of a multi-beam charged particle beam system;

FIG. 2 illustrates some details of a multi-beam charged particle beam system;

FIG. 3 illustrates at an example the effect of a sample charging during image acquisition;

FIG. 4 illustrates a detector with an optical relay system;

FIG. 5 illustrates a first example of a fast electrostatic element according to the first embodiment;

FIG. 6 illustrates a second example of a fast electrostatic element according to the first embodiment;

FIG. 7 illustrates a second embodiment;

FIGS. 8a,b illustrate an example of operation according to the second embodiment;

FIGS. 9a,b illustrates a third embodiment;

FIG. 10 illustrates a fourth embodiment;

FIG. 11 illustrates a fifth embodiment; and

FIG. 12 illustrates a sixth embodiment.

### DESCRIPTION OF EXEMPLARY EMBODIMENTS

In the exemplary embodiments of the disclosure described below, components similar in function and structure are indicated as far as possible by similar or identical reference numerals.

Some array elements, for example the plurality of primary charged particle beamlets, are identified by a reference number. Depending on the context, the same reference number may also identify a single element out of the plurality of elements. Each primary charged particle beamlet (3.1, 3.2, 3.3) is one beamlet of the plurality of primary charged particle beamlets (3).

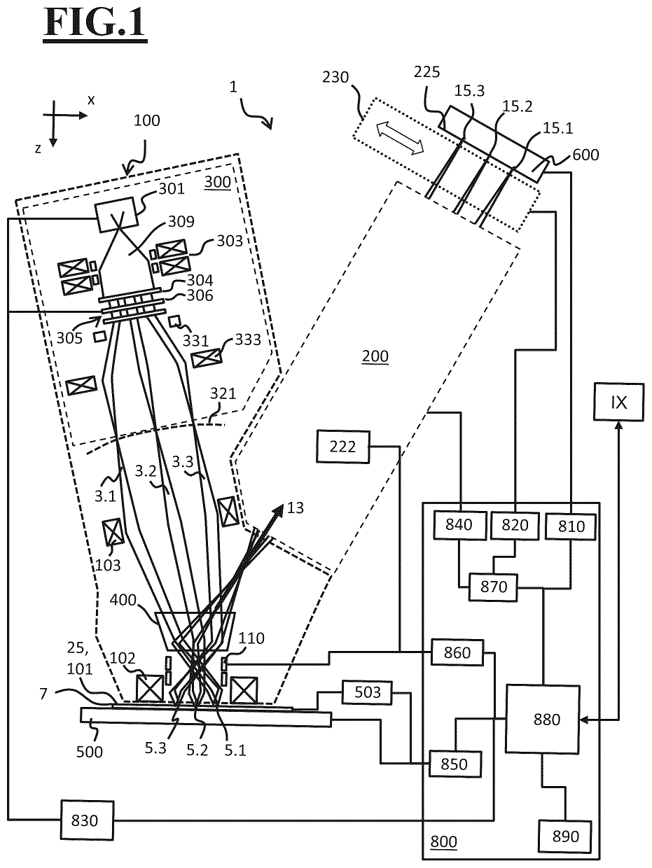

The schematic representation of FIG. 1 illustrates certain features and functions of a multi-beam charged-particle system 1. It is to be noted that the symbols used in the figure have been chosen to symbolize their respective functionality. The type of system shown is that of a multi-beam scanning electron microscope using a plurality of primary charged particle beamlets 3 for generating a plurality of primary charged particle beam spots 5 on a surface 25 of an object 7, such as a wafer or mask substrate located with a top surface 25 in an object plane 101 of an objective lens 102. For simplicity, only three primary charged particle beamlets 3.1 to 3.3 and three primary charged particle beam spots 5.1 to 5.3 are shown. The features and functions of multi-beamlet charged-particle system 1 can be implemented using electrons or other types of primary charged particles such as ions and in particular Helium ions. Further details of the microscope system 1 are provided in International Patent application WO 2022262970 A1, filed on Jun. 16, 2021, which is hereby fully incorporated by reference.

The system 1 comprises an object irradiation unit 100 and a detection unit 200 and a secondary electron beam divider or beam splitter unit 400 for separating the secondary charged-particle beam path 13 from the primary charged-particle beam path. The object irradiation unit 100 comprises a charged-particle multi-beam generator 300 for generating the plurality of primary charged-particle beamlets 3 and is adapted to focus the plurality of primary charged-particle beamlets 3 on the object plane 101, in which the surface 25 of an object or wafer 7 is positioned by a sample stage 500.

The primary beam generator 300 produces a plurality of primary charged particle beamlet spots in an intermediate image surface 321. The primary beamlet generator 300 comprises at least one source 301 of primary charged particles, for example electrons. The at least one primary charged particle source 301 emits a diverging primary charged particle beam, which is collimated by at least one collimating lens 303 to form a collimated or parallel primary charged particle beam 309. The collimating lens 303 is usually consisting of one or more electrostatic or magnetic lenses, or by a combination of electrostatic and magnetic lenses. The collimated primary charged particle beam 309 is incident on the primary multi-beam forming unit 305. A multi-beam generating unit 305 is for example explained in US 2019/0259575, and in U.S. Pat. No. 10,741,355 B1, both hereby incorporated by reference. The multi-beam forming unit 305 basically comprises a first multi-aperture plate or filter plate 304 illuminated by the collimated primary charged particle beam 309. The first multi-aperture plate or filter plate 304 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least one further multi-aperture plate 306, which is located, with respect to the direction of movement of the electrons in beam 309, downstream of the first multi-aperture or filter plate 304. For example, a second multi-aperture plate 306 comprises for example four or eight electrodes of electrostatic elements for each of the plurality of apertures, for example to individually deflect each beamlet of the plurality of beamlets. The multi-beamlet forming unit 305 is further configured with an adjacent electrostatic field lens 331, which is in some examples combined in the multi-beamlet forming unit 305. Together with a second field lens 333, the plurality of primary charged particle beamlets 3 is focused in or in proximity of the intermediate image surface 321. The primary charged-particle source 301 and each of the active multi-aperture plates 306 are controlled by control unit 830.

The plurality of focus points of primary charged particle beamlets 3, formed near the intermediate image surface 321, is imaged by field lens group 103 and objective lens 102 into the object plane 101, in which the surface 25 of the object 7 is positioned. A decelerating electrostatic field is generated between the objective lens 102 and the object surface 25 by application of a voltage to the object by the sample voltage supply 503. With the decelerating electrostatic field generated by sample voltage supply 503, a landing energy EL of primary electrons is adjusted to for example below 1 keV, below 800 eV, below 500 eV, below 300 eV or even less.

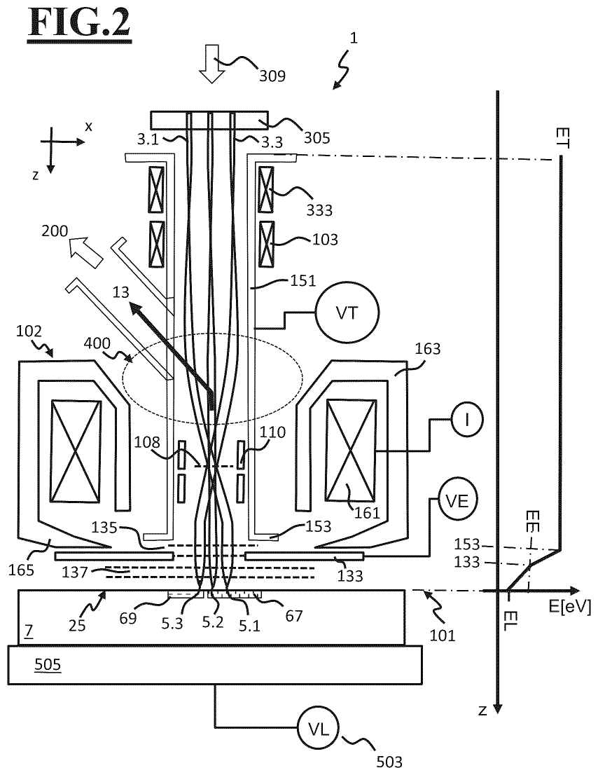

FIG. 2 illustrates further details of the decelerating electrostatic field generated. From a collimated electron beam 309, a plurality of primary charged particle beamlets 3 is generated by the multi-aperture arrangement 305. For simplicity, again only 3 beamlets 3.1 to 3.3 are shown in FIG. 2, but there can be more beamlets, for example more than 60, more than 90, or even more than 300 beamlets. A beam tube 151 is provided downstream of the multi-aperture arrangement 305, the beam tube 151 being connected to a voltage supply with the first or tube voltage VT. From the entrance of a beam tube 151, the plurality of primary charged particle beamlets 3 is at a constant kinetic energy ET (see energy plot at the right side of FIG. 2) until the exit opening 153 of the beam tube 151. The kinetic energy ET of the primary charged particle beamlets 3 during passing the beam tube 151 is for example 20 KeV, 30 keV or more.

The plurality of primary charged particle beamlets 3 are imaged and focus points 5.1 to 5.3 are formed in an object plane 101 by field lenses 333 and 103, and by objective lens 102. The objective lens 102 is of the type of a magnetic lens with a coil 161 and a pole shoe 163 with a lower pole shoe segment 165, forming an axial gap for the magnetic field. A current I is provided during use to the coil 161 to generate the focusing magnetic field (not shown). Other types of magnetic lenses are possible as well, for example radial gap lenses for generation an immersion lens field, or magnetic lenses with several coils and pole shoes. Upstream or partially integrated in the objective lens 102, a beam divider 400 is arranged, configured to separate the secondary electrons along secondary electron beam path 13 to detector unit 200. Below the lower pole shoe segment 165, an electrode 133 is provided, connected to a voltage supply for providing a second voltage VE to the electrode. In the example shown, the electrode 133 is provided as separate electrode.

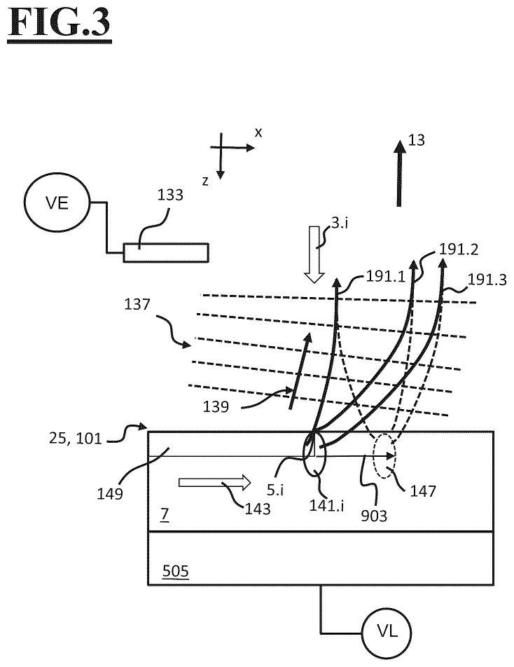

After leaving the beam tube 151, the plurality of primary charged particle beamlets 3 is decelerated from kinetic energy ET to a second kinetic energy EE. The voltage difference between VT and VE is responsible for the generation of a first electric field 135, illustrated in FIG. 2 with the equipotential lines of the first electric field 135. The first electrical field vectors are almost parallel to the propagation direction of the primary charged particle beamlets 3 and generate a decelerating force to the primary charged particles. The first voltage VE is typically adjusted such that the second kinetic energy EE is in a range below 5 keV, below 3 keV or even below 2 keV. Via sample voltage supple 503, a third sample voltage VL is provided by sample voltage supply 503 to a sample mounting platform 505 for holding and contacting during use a wafer 7. At the surface 25 of the wafer 7, a first material composition 67 is arranged under a first set of primary charged particle beamlets 3.1 and 3.2, and a second material composition 69 is arranged under a second set of primary charged particle beamlet comprising primary charged particle beamlet 3.3. According to the voltage difference between VL and VE, a second electrical field 137 is generated, which is almost parallel to the propagation direction of the primary charged particle beamlets 3 and generates a decelerating force to the primary charged particles. The third or sample voltage VL is adjusted such that the third kinetic energy or landing energy EL of the primary electrons is adjusted in a range below 800 eV, below 300 eV or even below 100 eV. The electrical fields 135 and 137 both form a decelerating field to reduce the kinetic energy of the primary charged particle beamlets 3 before impinging on the sample surface 25 arranged in the object plane 101, such that a high resolution is achieved. The first electrical field 135 also forms an accelerating field on secondary electrons extracted from the wafer 7. The second electrical field 137 forms an extraction field for extracting and accelerating secondary electrons from the wafer 7. The second field 137 is therefore also called the extraction field 137. The extraction mechanism is further illustrated in FIG. 3 in the presence of a charging effect. A primary charged particle beamlet 3.i is focused to focus point 5.i and impinges on the surface 25 of wafer 7 and forms an interaction volume 141.i in the wafer 7. During the operation at the low landing energies EL below 800 eV, below 300 eV or even below 100 eV, the interaction volume 141.i has a small extension below 5 nm or even less. The second or extraction field 137 extracts and accelerates secondary electrons generated in the interaction volume 141.i along electron trajectories (some example of electron trajectories 191.1 to 191.3 are shown) in opposite propagation direction to the primary electron beam direction. Together with the further acceleration by the first electric field (see FIG. 2), the secondary electrons are accelerated to kinetic energies ES approximately given by ES=ET-ES. Especially for low landing energies EL, the kinetic energy ES of the secondary electrons along secondary electron beam path 13 is therefore very large, for example 19 keV or 29 keV. A fast and precise compensation of any aberrations during an imaging of the secondary electrons with the detection unit 200 therefore includes a special mechanism. FIG. 3 illustrates the situation when a sample is charged by the scanning irradiation with primary charged particle beamlet 3.i. The primary beamlet 3.i is scanned in scanning direction 143 and leaves a scanned surface segment 149 with a residual charge. This charging of the scanned surface segment 149 deteriorates the extraction field 137 generated between wafer sample 7 and electrode 133 and causes a local tilt to an extraction field vector 139. The effect of the extraction field vector 139 is more pronounced to the secondary electron beamlets having a lower kinetic energy compared to the primary electrons of the impinging primary beamlet 3.1.

Therefore, the secondary electron trajectories 191.1 to 191.3 are deflected to a larger extend and a virtual interaction volume 147 appears with a lateral offset to the real interaction volume 141.i. As an effect, the virtual displacement of the virtual interaction volume 147 as virtual source of secondary electrons leads to a displacement and magnification change of the focus points 15 of the raster of secondary electron beamlets 9. In FIG. 3, the effect of a negative charging is illustrated, with an additional vector component to the extraction field vector in positive line scanning direction 143. In an equivalent way, a positive charging would add a vector component to the extraction field vector in negative line scanning direction 143.

The example illustrated in FIG. 2 shows a multi-beam charged particle beam system 1 with a two-stage deceleration field 135 and 137 and an additional electrode 133. In another example only a single decelerating or extraction field 137 is generated between exit aperture 153 of the beam tube 151 and a sample 7 mounted on the sample platform 505. In this case, the exit aperture 153 of the beam tube 151 has the role of the electrode 133 for the extraction field 137.

The object irradiation system 100 of the multi-beam charged particle beam system 1 shown in FIGS. 1 and 2 further comprises a collective multi-beam raster scanner 110 in proximity of a beam cross over 108 by which the plurality of charged particle beamlets 3 can be deflected in scanning direction 143 (see FIG. 3) perpendicular to the propagation direction of the charged particle beamlets. The propagation direction of the primary beamlets throughout the examples is in positive z-direction. Objective lens 102 and collective multi-beam raster scanner 110 are centered at an optical axis (not shown) of the multi-beam charged-particle system 1, which is perpendicular to wafer surface 25. The plurality of primary charged particle beamlets 3, forming the plurality of beam spots 5, which are arranged in a raster configuration, is scanned synchronously over the wafer surface 25. In an example, the raster configuration of the focus spots 5 of the plurality of J primary charged particle 3 is a hexagonal raster of about one hundred or more primary charged particle beamlets 3, for example J=91, J=100, or J approximately 300 or more beamlets. The primary beam spots 5 have a distance about 6 μm to 45 μm and a diameter of below 5 nm, for example 3 nm, 2 nm or even below. In an example, the beam spot size is about 3 nm, and the distance between two adjacent beam spots is 8 μm. At each scan position of each of the plurality of primary beam spots 5, a plurality of secondary electrons is generated, respectively, forming the plurality of secondary electron beamlets in the same raster configuration as the primary beam spots 5. The intensity of secondary charged particle beamlets generated at each beam spot 5 depends on the intensity of the impinging primary charged particle beamlet 3, illuminating the corresponding spot 5, the material compositions 67, 69 and topography of the object 7 under the beam spot 5, and the charging condition of the sample at the beam spot 5. The plurality of secondary charged particle beamlets are accelerated by the same electrostatic field between objective lens 102 and object surface 25 and are collected by objective lens 102 and pass the first collective multi-beam raster scanner 110 in opposite direction to the primary beamlets 3. The plurality of secondary beamlets is scanning deflected by the first collective multi-beam raster scanner 110. The plurality of secondary charged particle beamlets is then guided by secondary electron beam divider or beam splitter unit 400 to follow the secondary beam path 13 to the detection unit 200. The plurality of secondary electron beamlets is travelling in opposite direction of the primary charged particle beamlets 3 with kinetic energy ES=ET-EL. The beam splitter unit 400 is configured to separate the secondary beam path 11 from the primary beam path usually via magnetic fields or a combination of magnetic and electrostatic fields.

Detection unit 200 images the secondary electron beamlets onto the image sensor 600 to form there a plurality of secondary charged particle image spots 15 (see FIG. 1). The detector or image sensor 600 comprises a plurality of detector pixels or individual detectors. For each of the plurality of secondary charged particle beam spots 15, the intensity is detected separately, and the property of the object surface 25 is detected with high resolution for a large image patch of the object 7 with high throughput. For example, with a raster of 10×10 beamlets with 8 μm pitch, an image patch of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by control unit 800. Details of the digital image data collection and processing, using for example parallel processing, are described in international patent application WO 2020151904 A2 and in U.S. Pat. No. 9,536,702, which are hereby incorporated by reference.

Detection unit 200 further comprises at least a second raster scanner 222, which is connected to scanning control unit 860. Scanning control unit 860 is configured to compensate a difference in the scanning deflection power of the first scanning deflector 110 in the common beam path, such that the positions of the plurality secondary electron focus spots 15 are kept constant at image sensor 600. The difference in the scanning deflection power of the first scanning deflector 110 arises from the difference between the kinetic energy ET of primary electrons with respect to the kinetic energy ES of secondary electrons. The system 1 may further comprise an optionally retractable monitoring system 230. Monitoring systems and monitoring methods to detect charging effects at such charging samples are further described in patent applications WO 2022248141 A1 and DE 102022114923.4, which are hereby fully incorporated by reference. The detection unit 200 is described in more detail below.

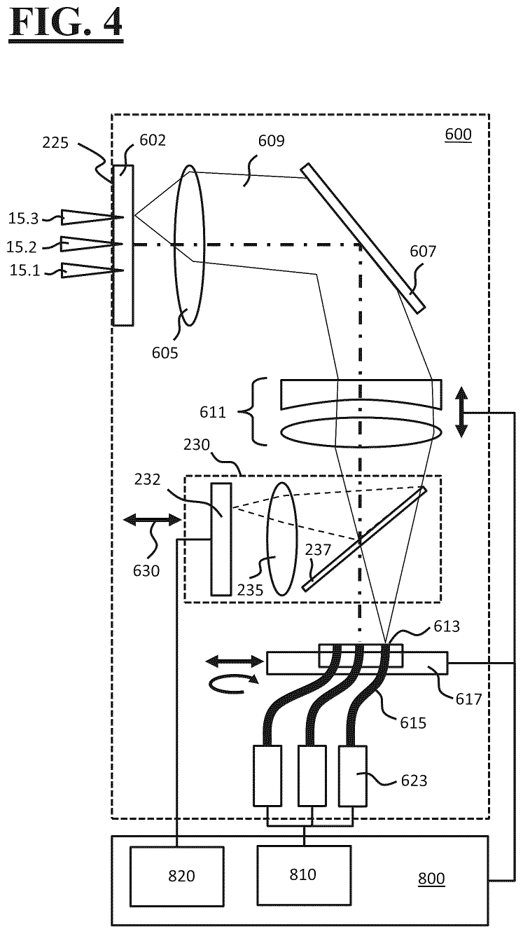

The image sensor 600 is configured by an array of sensing areas in a pattern compatible to the raster arrangement of the secondary electron beamlets focused by the detection unit 200 onto the image sensor 600. This enables a detection of each individual secondary electron beamlet independent from the other secondary electron beamlets incident on the image sensor 600. The image sensor 600 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 600 can be configured as electron to photon conversion unit or scintillator plate arranged in the focal plane of the plurality of secondary electron particle image spots 15. In this embodiment, as shown in FIG. 4, the image sensor 600 can further comprise a relay optical system comprising collection lenses 605 and zoom lens 611 for imaging and guiding the photons generated by the electron to photon conversion unit 602 at the secondary charged particle image spots 15 on dedicated photon detection elements 623, such as a plurality of photomultipliers or avalanche photodiodes. Such an image sensor is disclosed in U.S. Pat. No. 9,536,702, which is cited above and incorporated by reference. The image sensor is further configured with an optionally extractable monitoring system 230, comprising a beam divider mirror 237, an imaging lens 235 and a CMOS sensor 232 with high resolution.

During an acquisition of an image patch by scanning the plurality of primary charged particle beamlets 3, it is generally desirable for the stage 500 to not move, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

During an image scan, the control unit 800 is configured to trigger the image sensor 600 to detect in predetermined time intervals a plurality of timely resolved intensity signals from the plurality of secondary electron beamlets, and the digital image of an image patch is accumulated and stitched together from all scan positions of the plurality of primary charged particle beamlets 3.

The control unit 800 of the multi-beamlet charged-particle system 1 further comprises an—imaging control module 810, configured to receive the data streams from the image sensor 600 and to generate a digital image of the surface of the sample 7 during operation; a secondary beam-path control module 840, configured to control the detection unit 200; a primary beam-path control module 830, configured to control the elements of the object irradiation unit 100; a stage control module 850, configured to control the stage positioning and alignment, and including control of the sample voltage supply unit 503; a scanning operation control module 860, configured to control a scanning operation by the first collective multi-beam raster scanner 110 and the second deflection system 222; a control operation processor unit 880, configured to execute inspection tasks of samples, and configured to control the modules 810, 820, 830, 840, 850, 860; and a memory 890 for storing software, instructions and image data. The control operation processor unit 880 is further connected to an interface IX for exchange of data, instructions, software or user interaction.

The control unit 800 of the multi-beamlet charged-particle system 1 according to the disclosure further comprises a contrast control module 870, connected to the control operation processor unit 880. The contrast control module 870 is configured to receive instructions from the control operation processor unit 880 to control a compensation of charging effects during the imaging of secondary electrons onto the image sensor 600. The contrast control module 870 is connected to a sensor module 820, connected to the monitoring system 230.

When sample charging occurs as illustrated in FIG. 3, the trajectories of the secondary electron path are distorted. As a result, the detector 600 is no longer correctly hit by the secondary electron beamlets. In a worst case, this can result in dark images, or in large crosstalk. Generally, due to sample charging effects, an image contrast changes across the field of view of the multi-beam charged particle beam system 1, making evaluation of the images of for example a wafer surface 25 coated with resist very difficult.

According to a first embodiment, fast lenses for high-energy secondary charged particle beamlets at kinetic energy ES above 15 keV, above 20 keV or even 30 keV are provided. The fast lenses are configured to compensate for changes induced by sample charging during a wafer inspection task. The changes considered are changes in image magnification, image rotation, focus position and telecentricity of the plurality of secondary electron beamlets. The set of fast lenses is further capable to compensate for changes due to charging effects for varying kinetic energy of the secondary electrons. The kinetic energy ES of the secondary electron beamlets and the secondary electron beam paths in the detection unit 200 vary largely with the different landing energy EL of the primary electrons with landing energies of primary electrons between 200 eV and 800 eV, or even between 100 eV and 2 keV, being adjusted for example by the sample voltage VL.

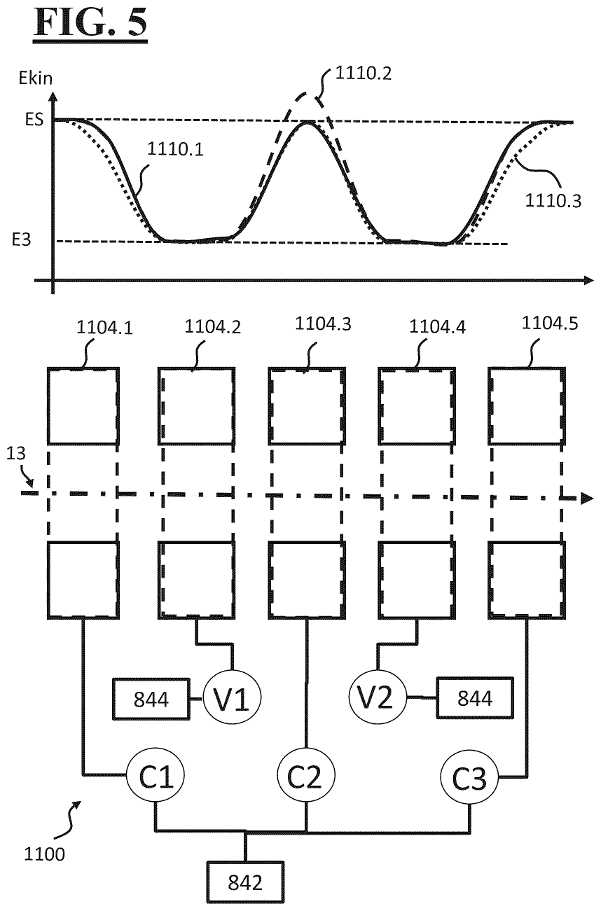

In a first example, a fast electrostatic lens element 1100 configured for fast compensation of charging effects is provided with five ring-shaped electrodes. An example is illustrated in FIG. 5. The fast electrostatic lens 1100 according to the first example comprises an outer pair of electrodes 1104.1 and 1104.5 and a group of three inner electrodes 1104.1, 1104.2 and 1104.3, a first, dynamic power supply unit 842 and a second, static power supply unit 844. Each electrode has the form of a disk with a central aperture for passing the plurality of secondary electron beamlets. The first electrode 1104.1 is provided during use with a low voltage C1. The second electrode 1104.2 in propagation direction of the secondary electron beam path 13 (indicated by arrow 13) is during use on high voltage V1 and serves to decelerate the secondary electrons from high kinetic energy ES to lower, third kinetic energy E3. The high voltage is for example about-10 kV. The kinetic energy ES is for example reduced to the third kinetic energy E3 by 20% or more, for example by 30%. With a kinetic energy ES of for example 30 keV, the third kinetic energy E3 is for example E3=22 keV or even less, for example 20 keV or 18 keV. The third electrode or center electrode 1104.3 is provided during use with a second, variable low voltage C2, which is small and for example close to ground potential. The voltage range of C2 is for example about +/−250V, or up to +/−500V. The fourth electrode 1104.4 is provided again with a large voltage V2 and is configured to accelerate the secondary electrons again to kinetic energy close to ES. In an example, V2 is equal to V1. The fifth electrode 1104.5 is provided during use with a third low voltage C3. In an example, static high voltages V1 and V2 are provided by static voltage unit 844 to the second and fourth electrodes 1104.2, 1104.4. The low voltages C1, C2 and C3 are provided by first, dynamic power supply unit 842 to the outer pair of electrodes 1104.1 and 1104.5 and to the center electrode 1104.3. An example of the kinetic energy 1110.1 of secondary electrons during passage through the fast electrostatic lens element 1100 is illustrated in FIG. 5 above the fast electrostatic lens element 1100. During use, the first, dynamic power supply unit 842 receives control commands from contrast control unit 870 and is configured to generate fast changes to the low voltages C1, C2 and C3. In an example, only voltage C2 is adjusted during use by first, dynamic power supply unit 842 to quickly cause a variable lens power (as illustrated at an example of an increased kinetic energy 1110.2 during passage of the central electrode 1104.3) within the fast electrostatic lens element 1100. Thereby, a high dynamic change of a lens power is achieved, and a charging effect is compensated during use. In an example, low voltages C1 and C3 are adjusted during use by first, dynamic power supply unit 842 to quickly cause a variable lens power (as illustrated at an example of a further reduced kinetic energy 1110.3 during passage of the electrodes 1104.1 and 1104.5). Thereby, a high dynamic change of a lens power is achieved, and a charging effect is compensated during use. In an example, low voltages C1, C2 and C3 are adjusted during use by first, dynamic power supply unit 842 to quickly cause a change of the lens power. Thereby, a charging effect is compensated during use. It is to be noted that, for illustration, the effect of the small changes to low voltages C₁ to C₃ is highly exaggerated in FIG. 5.

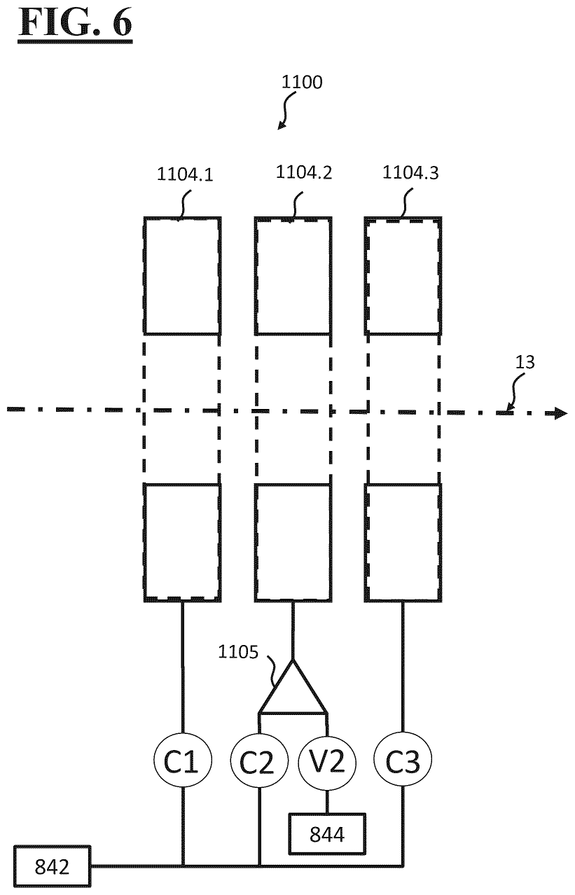

In a second example, an electrostatic lens element 1100 configured for fast compensation of charging effects is provided with three electrodes. An example is illustrated in FIG. 6. The electrostatic lens element 1100 comprises a first electrode 1104.1, a second electrode 1104.2, and a third electrode 1104.3. During use, the center electrodes 1104.2 is provided with a static high voltage V2 by the second, static voltage supply unit 844. For example, static voltages V2 is a large voltage about V2=−10 keV, sufficient to cause a strong lens action to the secondary electrons. During use, at least one variable low voltage C1, C2 or C3 is provided by the first, dynamic voltage supply unit 842. For example, a variable low voltage C2 is added by a voltage adder 1105 to the high voltage V2. For example, during use, the first, dynamic power supply unit 842 receives control commands from contrast control unit 870 and is configured to generate fast changes to the low voltage C2. In an example, only voltage C2 is adjusted during use by first power supply unit 842 to cause a variable lens power within the electrode arrangement 1100. Thereby, a charging effect is compensated during use. In a further example, during use, variable low voltages C1 and C3 are provided to first and third electrodes 1104.1 and 1104.3 to cause a variable lens power within the electrode arrangement 1100 in a similar manner as described in conjunction with FIG. 5.

The first and the second example of the first embodiment, fast electrostatic elements 1100 are provided, which can be changed quickly by changing a low voltage provided by first power supply unit 842, while the high voltages provided by second power supply unit 844 are static and are not changed. A fast electrostatic element 1100 comprises at least 3 electrodes 1104. A fast electrostatic element 1100 can also comprise a larger number N of electrodes, with for example N=5, N=7 or more. A fast electrostatic element 1100 is achieved by a first, dynamic low voltage supply unit 842 configured for adjusting at least one low voltage Ci and providing the at least one low voltage Ci to at least one electrode 1104.i (with i=1 . . . . N). The fast electrostatic element 1100 further comprises a second, static voltage supply unit 844 for providing at least two static high voltages Vj, Vk to at least two electrodes 1104.j and 1104.k (with j, k=1 . . . . N).

In an example, at least one electrode 1104.i of a fast electrostatic element 1100 is configured to be provided with at least one high voltage bias Vi with voltages above several kV, for example 8 kV, 10 kV or more. The fast electrostatic element 1100 further comprises at least one voltage adder 1105 for adding a high voltage Vi and a low, dynamically changing voltage Ci and providing the combined voltages Vi and Ci to an electrode 1104.i (with i=1 . . . . N).

The variable low voltages Ci are in a range between-250V and +250V, or in a range between-500V and +500V. Such low voltages can quickly be changed by a first, dynamic low voltage supply unit 842.

In a second embodiment according to the disclosure, at least two electrostatic elements 211 are provided in a detection unit 200 to control magnification and focus at the detector 600 of the secondary electron imaging path 13 over a wide range of landing energies EL. The at least two electrostatic elements 211.1 and 211.2 are used to compensate the dependency of the electron optical elements of the detection unit 200 on different secondary electron energies ES and the corresponding large variation of the secondary electron beam path 13 during passage of the detection system 200. A explained above, a variation of secondary electron beam energy ES is achieved by changing the sample voltage VL by sample voltage supply unit 503. In an example, an additional minor variation of secondary electron beam energy ES is caused by charging effects of the sample, by which the kinetic energy ES of secondary electrons is either increased or reduced.

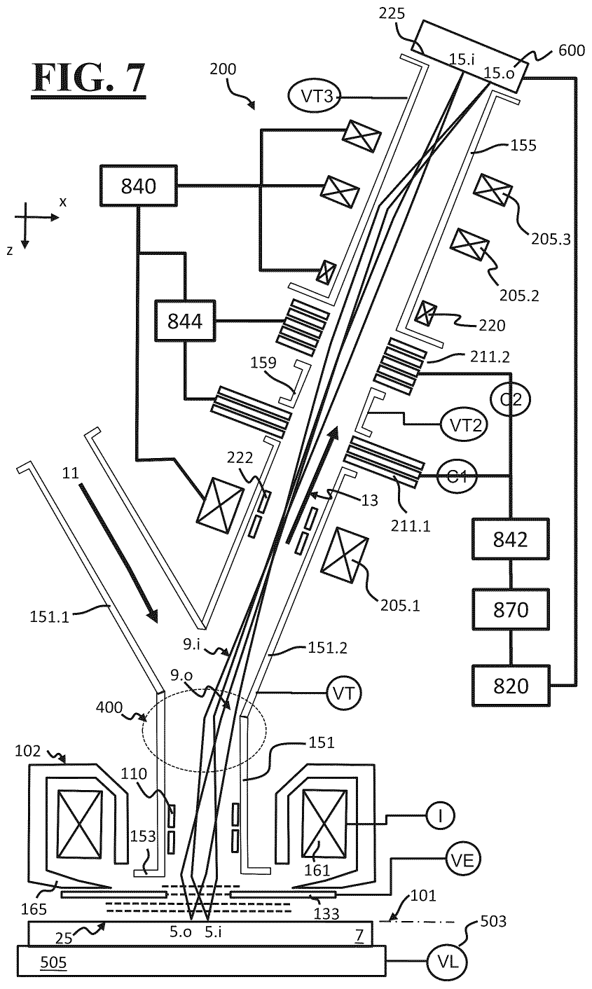

FIG. 7 illustrates a first example of the second embodiment. FIG. 7 illustrates the detection unit 200 and further components, which are already shown in FIG. 1 or FIG. 2, and which are labelled by same reference numbers. Reference is made to the description of FIGS. 1 and 2. The primary charged particle beamlets are schematically shown by primary beam path 11. The FIG. 7 illustrates the secondary electron beam path at the example of two secondary electron beamlets 9.i and 9.0 at a first landing energy EL of primary electrons. There are many more secondary electron beamlets, corresponding to the number of the plurality of primary charged particle beamlets, which are focused onto the surface 25 of a sample 7 (with only to focus points 5.0 and 5.i shown). The detection unit 200 comprises a second branch 151.2 of the common beam tube 151, which is connected to a voltage supply line and set to tube voltage VT (see also FIG. 2). VT can for example be ground potential. Through the tube 151, primary charged particles propagate with constant high kinetic energy of for example E1=30 keV. Through the tube 151, secondary electrons propagate with constant high kinetic energy of for example E2=E1−EL, with E2 between 28 keV and 30 keV. With the second embodiment, a fast, dynamic change of a secondary electron beam of such high kinetic energy is enabled. The detection unit 200 further comprises a second beam tube segment 159 at tube voltage VT2 and a third beam tube segment at tube voltage VT3. In an example, VT, VT2 and VT3 are identical and all set to ground level. Between the second branch 151.2 and the second beam tube segment 159, a first fast electrostatic lens element 211.1 is arranged. In this example, the first fast electrostatic lens element 211.1 is configured as fast electrostatic lens 1100 according to the second example of the first embodiment with three electrodes. Between the second beam tube segment 159 and the third beam tube segment 155, a second fast electrostatic lens element 211.2 is arranged. In this example, the second fast electrostatic lens element 211.2 is configured as fast electrostatic lens 1100 according to the first example of the first embodiment with five or more electrodes. Upstream of the first fast electrostatic lens element 211.1 in propagation direction of the secondary electron path 13, a first magnetic projection lens 205.1 and the second scanning deflector 222 are arranged. In this example, the second scanning deflector 222 is a two-stage electrostatic octupole scanner, which is arranged inside the second branch 151.2 of the common beam tube 151. Downstream of the second fast electrostatic lens element 211.2, at least one static deflector or multi-pole corrector 220 for quasi-static adjustment of a secondary electron beam path and two further magnetic projection lenses 205.2 and 205.3 are provided. A pair of two further magnetic projection lenses 205.2 and 205.3 are configured to form the focus spots 15.i, 15.0 of the secondary electron beamlets 9.i, 9.0 on the image plane 225 and to adjust an image rotation of the secondary electrons beamlets, induced by for example a change of an object plane 101 by objective lens 102. The three magnetic projection lenses 205.1, 205.2 and 205.3 and the quasi-static multi-pole corrector 220 are connected to and controlled by the secondary beam-path control module 840 according to the selected landing energy EL. Additional magneto-dynamic multi-pole deflectors (not shown) may be arranged for a quasi-static adjustment of the beam path 13 of the plurality of secondary electron beamlets 9.

The two fast electrostatic lenses 211.1 and 211.2 are connected to and controlled by secondary beam-path control module 840, which is configured to provide quasi-static high offset voltages to at least one of the electrodes of a fast electrostatic lens 211.1 or 211.2. The two fast electrostatic lenses 211.1 and 211.2 are further connected to and controlled by a first dynamic voltage supply unit 842, which is connected to contrast control module 870. The first dynamic voltage supply unit 842 is configured to provide dynamic low voltages C1 and C2 to at least one electrode of each of the fast electrostatic lenses 211.1 and 211.2. Contrast control module 870 is connected to sensor control module 820, which receives signals from monitoring system 230, which is in this example arranged within the image sensor 600. Contrast control module 870 is configured to receive a signal corresponding to a charging effect from sensor control module 820 and to determine a change to the dynamic low voltages C1 and C2 in order to compensate the charging effect.

The sample 7 is connected to sample holder 505 und provided with sample voltage VL by sample voltage supply 503. Depending on the sample voltage VL or sample potential, secondary electrons are extracted and accelerated into a wide range of kinetic energies ES. For example, at a first high landing energy EL1 about 1 keV, secondary electrons of a first, lower kinetic energy ES1 are generated, for example with ES1=29 keV. For example, at a second, low landing energy EL2 about 300 eV, secondary electrons of a second, higher kinetic energy ES2 are generated, for example with ES2=29.7 keV. With the predetermined variation of landing energy ES between below 300 eV and more than 1 keV, for example up to 2 keV or even 3 keV, the kinetic energy ES of secondary electrons may vary in a wide range of up to 1 keV, up to 2 keV, or even more than 2 keV. With the lens arrangement of the detection unit 200 described above, a fast correction of charging induced effects is possible for a wide range of kinetic energies ES of secondary electrons.

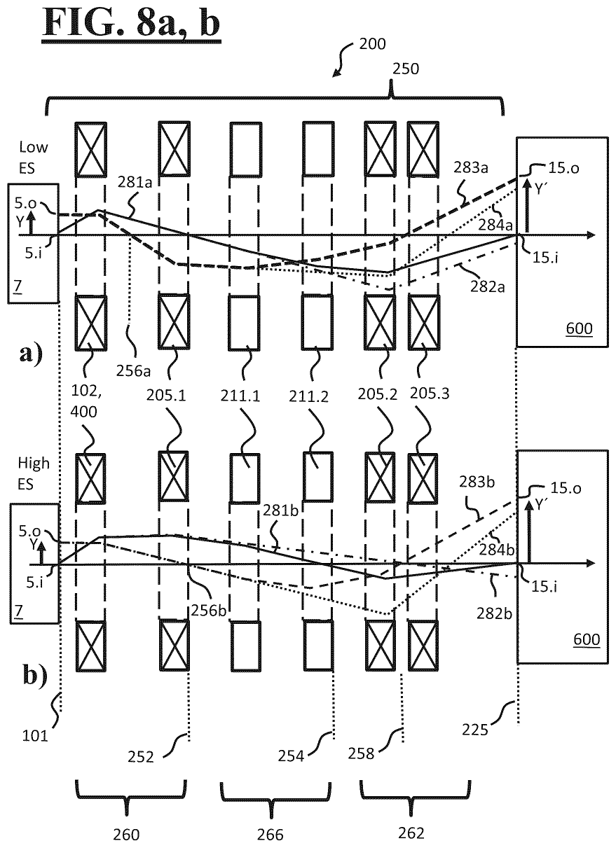

Furthermore, any accumulated charge generates an additional charging voltage VC proportional to the accumulated charge Q divided by the local capacity C to hold charges. Since isolators and some semiconductor structures have a very small capacities, even small charges in a structured semiconductor wafers may cause large local voltage differences of up to 100V or even more. The kinetic energy ES of secondary electrons thus depends on quasistatic and predetermined variations of the sample voltage VL or landing energy EL of primary electrons over the large range described above, and kinetic energy ES of secondary electrons further depends on an additional, fast variation energy component EC due to charging effects, wherein the fast variation component of the kinetic energy is in a range of up to +/−100 eV, or up to +/−200 eV. FIGS. 8a and b illustrate two examples of different settings of the lens arrangement of the detection unit 200, including the two fast correction lenses 211.1 and 211.2. The lens elements 102, 400, and 205.1 to 205.3 are labelled with the same reference numbers of FIG. 7 and reference is made to FIG. 7. FIG. 8a illustrates an example with a first, large landing energy EL1, and consequently a lower kinetic energy ES1 of secondary electrons. Electron trajectory 282a illustrates a secondary electron trajectory starting from an axial focus point 5.i in presence of a local charging with additional voltage VC1 of about 100 eV. With a predefined actuation of fast correction elements 211.1 and 211.2, the effect of the change of the kinetic energy ES1 to ES1+/−VC1 is compensated, and secondary electrons follow trajectory 281a instead, and an image point 15.i on axis is formed. Electron trajectory 284a illustrates a secondary electron trajectory starting from an off axis focus point 5.0 at object height Y in presence of a local charging with additional voltage VC1 of about 100 eV. With a predefined actuation of fast correction elements 211.1 and 211.2, the effect of the change of the kinetic energy ES1 to ES1+/−VC1 is compensated, and secondary electrons follow trajectory 283a instead and form an image point 15.0 at image height Y′=M times Y, with the desired and constant magnification M of for example M=20. FIG. 8b illustrates an example with a smaller landing energy EL2, and consequently a higher kinetic energy ES2 of secondary electrons. Secondary electron trajectories are labeled with same reference numbers and label b for the second, higher kinetic energy ES2. The different secondary electron trajectories are a consequence of the different actuation of the detection unit 200 by secondary beam-path control module 840 according to the second landing energy EL2. With the actuation of fast correction elements 211.1 and 211.2, an imaging of the secondary electrons starting from the surface of the wafer 7 into the image plane 225 of the detection unit 200 is maintained at constant, predefined magnification. With two fast correction elements 211.1 and 211.2, magnification M and axial focus position of focus spots 15 of the secondary electron beamlets 9 are controlled.

Each secondary electron beamlet 9 is originating from an interaction volume 141 (see FIG. 3) of a primary charged particle beamlet 3 with the sample 7 at a focus point 5 of a primary beamlet 3 in object plane 101. The projection system 250 of the detection unit 200 for imaging of the secondary beamlets into the image plane 225 comprises a first group of lenses 260 to form a first cross section or pupil plane 256 within the first group of magneto-dynamic lenses 260. The first group of lenses 260 further forms a first intermediate image plane between a low-energy intermediate image position 252 and high energy intermediate image position 254. The first group of lenses 260 is consisting of the objective lens 102 and the first magnetic projection lens 205.1. The beam divider 400 may further contribute to the imaging of the first group of lenses 260. The objective lens 102 and beam splitter 400 are also part of the object irradiation unit 100 (see FIG. 1) and their setting is determined according to the focus point formation of the primary charged particle beamlets 3 with a predetermined landing energy EL. Therefore, the only independent lens parameter of the first group of lenses 260 of the projection system 250 is given by the first magnetic projection lens 205.1. The projection system 250 comprises a second group of lenses 262 to form the image plane 225 of the detection unit 200. The second group of lenses 262 is consisting of a pair of lenses comprising the second and third magnetic projection lenses 205.2 and 205.3. With both projection lenses 205.2 and 205.3, an image rotation of the first group of lenses 260 is compensated, such that the raster positions of secondary electron focus spots 15 on the image sensor 600 are kept at constant rotation angle. Within the second group of lenses 262, a fixed position of a cross over or pupil 258 is formed, in which for example an aperture stop can be arranged. Aperture stops are for example disclosed in U.S. provisional application Ser. No. 17/966,026, filed on Oct. 14, 2022, which is incorporated herein by reference. During use, the projection lenses 205.1 to 205.3 are controlled by second beam-path control unit 840 to image the secondary electron beamlets 9 into the image plane 225 of the detection unit 200 according to the different, selected landing energies within a wide range of landing energies EL of primary charged particles between less than 300 eV, for example 200 eV or 100 eV, and more than 1 keV, for example 2 keV.

The projection system 250 further comprises a group of correction lenses or charge compensation group 266, comprising at least two fast correction lenses 211.1 and 211.2. The group of correction lenses 266 is arranged between the first, low-energy intermediate image position 252 and a second, high-energy intermediate image position 254. The group of correction lenses 266 is arranged upstream of the second group of lenses 262 and a second cross-over or pupil position 258. During use, the two fast correction lenses 211.1 and 211.2 are controlled by second beam-path control unit 840 and the contrast control module 870, configured to quickly change the lens powers of the two fast correction lenses 211.1 and 211.2 to compensate charging effects within a sample 7 during image scanning at scanning frequencies of more than 20 MHz, for example 50 MHz or even more. The fast mechanism for charge compensation according to the second embodiment are therefore configured to compensate fast changes in magnification and focus position of the secondary electrons due to charging effects over a wide range of landing energies EL of primary charged particles. In an example, the two electrostatic elements 211.1, 211.2 are each configured as fast electrostatic elements 1100 according to the first embodiment.

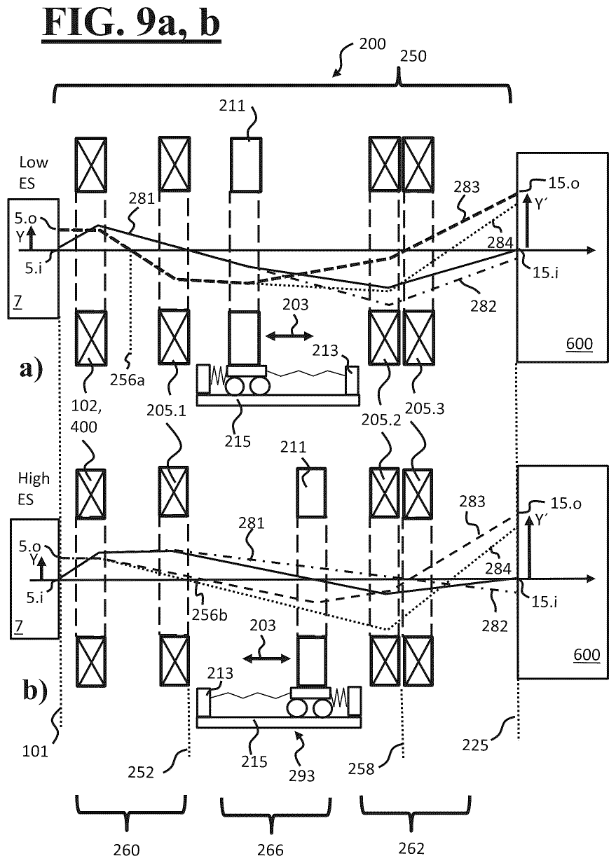

The fast mechanism for charge compensation according to a third embodiment comprises a single fast electrostatic element 211 and a mechanical manipulator as a further mechanism for charge compensation. The mechanical manipulator is configured to adjust an axial position of the single fast electrostatic element 211. FIG. 9 illustrates a projection system 250 of the detection unit 200 according to the third embodiment. Same reference numbers are used in FIGS. 8a and b and reference is made to the description of FIGS. 8a and b as well. The projection system 250 of the detection unit 200 according to the third embodiment comprises a single fast electrostatic element 211 with adjustable axial position in axial direction 203. The fast electrostatic element 211 is mounted on a mechanical manipulator 293 comprising an actuator 213 and a guide bearing 215 configured for manipulation of the axial position of the fast electrostatic element 211. An actuator 213 can comprise any mechanical actuator such as a motion drive, a pneumatic actuator, or a piezo element. A guide bearing 215 can comprise a sliding support, a solid-state parallel motion, a hexapod, or a double thread. According to a predetermined landing energy EL of primary charged particles, the axial position of fast electrostatic element 211 is adjusted by actuator 213 to a predetermined axial position for a given landing energy EL. The actuator 213 is controlled by secondary beam-path control module 840. During use, charging effects such as magnification changes and focus plane deviations are compensated by the single fast electrostatic element 211 at its predetermined axial position. With the axial position adjustment of the single fast electrostatic element 211, a fast charge compensation with an imaging at constant magnification and focus position is achieved over a wide range of different landing energies of primary charged particles. In an example, the single electrostatic element 211 is configured as fast electrostatic element 1100 according to the first embodiment.

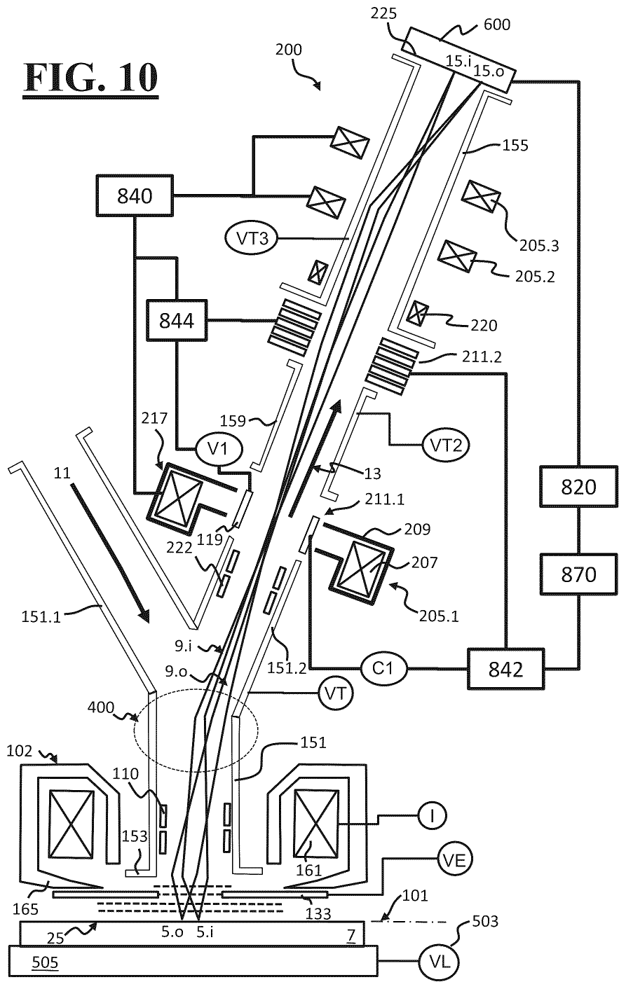

FIG. 10 illustrates a fourth embodiment. The fast mechanism for charge compensation according to a fourth embodiment is achieved by a fast hybrid lens 217, comprising a single fast electrostatic element 211.1 integrated into the first magneto-dynamic lens 205.1. Magneto-dynamic lenses do not allow for a fast change of a lens power. According to the fourth embodiment, the beam tube is segmented in the proximity of a magneto-dynamic lens into a first segment 151.2, a lens tube segment 119 and a second tube segment 159. The first segment 151.2 is for example part of the common beam tube 151 and set to voltage level VT, which is for example ground level. The second tube segment 159 is set to VT2, which is for example equal to VT. During passage of tube segments 151.2 and 159, secondary electrons are at the same kinetic energy ES. The lens tube segment 119 is on a quasi-static high voltage V1 combined with a dynamic variable low voltage C1, configured to compensate for charging effects at the sample 7. The control of the three tube segments is configured similar to the control of the second example according to the first embodiment and allows a fast variation of the lens power of the hybrid lens 217. The change of the lens power is here two-fold: first, the kinetic energy and thus the velocity of the secondary electrons is changed during passage of the lens tube segment 119 and during passage through the magnetic field generated by magneto-dynamic projection lens 205.1. In the example shown in FIG. 10, the magnetic field of projection lens 205.1, exited by lens coil 207, is limited by yoke or pole shoe 209 to an axial region of the lens tube segment 119. Thereby, a fast change of the lens power of the constant magneto-dynamic projection lens 205.1 is achieved via a fast change of the velocity of secondary electrons. Second, the three tube segments 151.2, 119 and 155 form an Einzel lens similar to the second example of the first embodiment. Such a fast hybrid lens 217 according to the fourth embodiment shown in FIG. 10 is not limited to the first projection lens 205.1, but can be applied to each other projection lens 205.2 or 205.3, or any combination of them. In particular, an additional hybrid lens can be provided to correct the resulting rotation change from the other magneto-dynamic lens elements instead of the two projection lenses 205.2 and 205.3.

With the two-fold fast adjustment of a lens power with a fast electrostatic element 211 integrated into a magneto-dynamic lens, a fast charge compensation with an imaging at constant magnification and focus position is achieved over a wide range of different landing energies EL of primary charged particles.

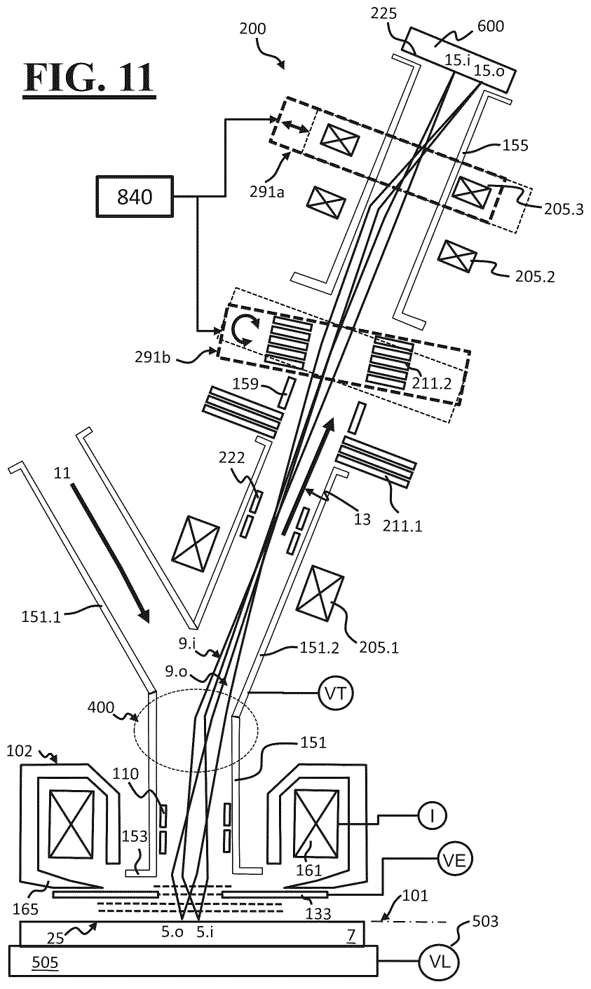

A detection unit 200 according to the disclosure comprises therefore a reduced number of electro-optical elements including at least one fast electro-static element 211 for compensation of charge induced effects at a sample 7 over a large range of landing energies EL of primary charged particles. A detection unit 200 according to the disclosure is therefore of reduced complexity. A detection unit 200 according to the disclosure comprises a projection system 250, which is formed by an objective lens 102, a beam divider 400, and not more the three magneto-dynamic lenses 205.1, 205.2 and 205.3. The projection system 250 further comprises one or two fast electrostatic lens elements 211 or 211.1 and 211.2. The detection unit 200 further comprises a second raster scanner 222 and at least one static deflector or multi-pole corrector 220 for static adjustment of a secondary electron beam path. A detection unit 200 of even further reduced complexity is given in the fifth embodiment. FIG. 11 illustrates an example of a detection unit 200. Same reference numbers as in FIG. 7 are used and reference is made to the description of FIG. 7. The detection unit 200 according to the fifth embodiment comprises at least one, in this example two electro-optical elements mounted via a positioning actuator 291a and 291b within the detection unit 200. Thereby, the multi-pole deflection element 220 can be omitted. A first position actuator 291a is configured for a lateral displacement of a magneto-dynamic projection lens 205.3. A second position actuator 219b is configure for a tilt adjustment of a fast electrostatic lens element 211.2. Such a tilt adjustment can also be combined with an adjustment in axial direction 217 according to the third embodiment, illustrated in FIGS. 9a and b, for example with a hexapod actuator. Other mechanical solutions to enable a mechanical adjustment typically comprise at least an actuator and guide bearings, as described above. A mechanical adjustment mechanism can further comprise sensor to a sensor-controlled precision adjustment of an electro-optical element. Mechanical solutions to enable a mechanical adjustment of electro-optical elements are further disclosed in German patent application 102022114098.9, filed on Jun. 3, 2022, which is incorporated herein by reference. Position actuators 291a and 291b are controlled by secondary beam-path control module 840. Actual position of the position actuators 291a and 291b can be pre-determined during a calibration for different landing energies EL of primary charged particles and can be adjusted during setting adjustment of the detection unit 200 for different landing energies EL of primary charged particles.

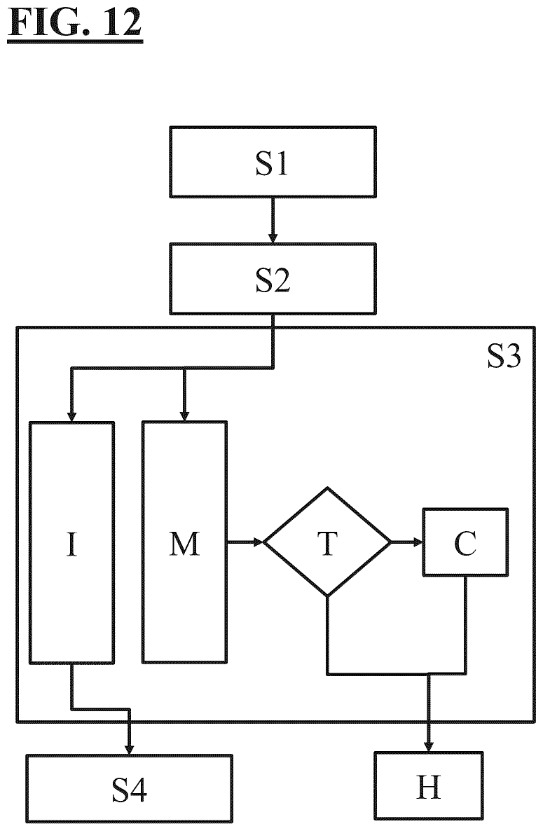

A method of operation of a multi-beam charged particle beam system is described in a sixth embodiment. An example of the sixth embodiment is illustrated in FIG. 12.

In step S1, a wafer 7 is placed on the sample mounting platform 505 and an inspection position on the upper surface 25 of the wafer 7 is positioned in the object plane 101 by stage 500. Step S1 further comprises the selection of an imaging setting for an inspection task. The selected image setting for performing an inspection task comprises a set of imaging parameters, for which a multi-beam charged particle beam system can be adjusted for. For example, one imaging parameter is the landing energy EL of primary charged particles, which is for example selected according to a desired resolution of an inspection task. Further image parameters comprise
the magnification of the object irradiation unit, by with a first pitch between the primary charged particle beamlets in an object plane 101 is adjusted and the magnification of the detection unit 200, such the secondary electron beamlets are focused on corresponding detection elements at a given second pitch within the image sensor 600;
the position of the object plane 101 of the object irradiation unit 100, for example by adjustment of a working distance WD between a reference plane of the objective lens 102 and object plane 101;
a numerical aperture of each of the plurality of primary charged particle beamlets in the object plane 101;
a beam current and scanning speed, which is for example selected according to a desired an image noise level.

In step S2, the multi-beam charged particle beam system 1 is adjusted according to the imaging setting selected in step S1. Step S2 comprises an adjustment of the charged-particle multi-beamlet generator 300, the object irradiation unit 100 and the detection unit 200. The quasi-static adjustment is controlled and executed by primary beam-path control module 830, secondary beam-path control module 840 and stage control module 850. The adjustment of a selected image setting comprises the adjustment of the landing energy EL of primary charged particles by stage control module 850, configured to provide a selected sample voltage VS to a wafer 7 mounted on sample mounting platform 505 via sample voltage supply 503. The adjustment of the imaging setting further comprises an adjustment of the static, high voltages to be provided to a fast electrostatic element 211 by the second static voltage supply unit 844. In an example, the adjustment of the imaging setting further comprises an adjustment of an axial or lateral position or a tilt angle of at least one electro-optical element by a positioning actuator. All adjustment values, such as the quasi-static voltages and currents can be predetermined during a calibration operation of the multi-beam charged particle beam system 1 and can be stored for each calibrated image setting in memory 890 of the control unit 800.

In step S3, an inspection is performed with the image setting at the inspection position. The inspection comprises an imaging scanning acquisition step I and a parallel monitoring step M. During the imaging scanning acquisition step I, the plurality of primary charged particle beamlets 3 are scanned by collective multi-beam raster scanner 110 and in parallel, image data are received by image detector 600. During imaging scanning acquisition step I, the second raster scanner 222 is operated to keep the focus spots 15 of secondary electron beamlets 9 at fixed positions at the image sensor 600. During monitoring step M, the positions of the focus spots 15 of the secondary electron beamlets 9 are determined and a magnification change or focus plane change is determined. The monitoring step M is for example performed by a monitoring system 230 and sensor module 820. The magnification and focus plane changes are transferred into compensation signals in step T, for example by pre-determined linear factors or transfer matrixes. In a parallel and fast compensation step C, the compensation signals are converted for example by digital to analog converters and an amplifier of the first, dynamic voltage supply unit 842 into quickly changing, low voltages C for compensation of charging effects. The monitoring step M, transfer step t and adjustment step C are continuously running and executed continuously during the scanning image acquisition step I and performed during an image scanning operation. During an image scanning operation, an image scanning is for example performed at a scanning frequency of 20 MHz or more, for example 50 Mhz or 80 MHz. A compensation of charging effects including monitoring step M, transfer step T and compensation step C is typically only limited by the monitoring step M, comprising the acquisition of the positions of the focus spots 15 of the secondary electron beamlets 9. In an example, the monitoring step M is performed with an image sensor with few Hz, for example 30 frames per second, up to 100 frames per second, or up to 200 frames per second. In an example, the monitoring step M is performed with additional monitoring sensors as for example disclosed in German patent application 102022114923.4, filed on Jun. 14, 2022, which is hereby incorporated herein by reference. With the monitoring, transfer, and compensation steps during and parallel to scanning image acquisition step I, a sample charging effect is continuously and dynamically compensated.

In step S4, the image obtained in scanning image acquisition step I is stored and further processed, for example a stitching operation is performed, or a dynamic contrast-adjustment is performed.

In step H, the continuous change of magnification or focus position or the continuous dynamic change of control voltages C is recorded and stored in a memory 890 of the control unit 800 for later use. A later use can for example be an analysis of a charging effect, a comparison to charging effects at other inspection sites, or a later application in a model-based charge compensation.

The disclosure can further be described by following set of clauses:
Clause 1: A multi-beam charged particle beam system (1), comprising:
   a charged-particle multi-beamlet generator (300) for generating a plurality of primary charged particle beamlets (3);
   an object irradiation unit (100), comprising a beam divider (400) and an objective lens (102) for forming a plurality of focus spots (5) of the plurality of primary charged particle beamlets (3) in an object plane (101), in which a surface (25) of a wafer (7) can be arranged;
   a voltage supply unit (503) configured to provide during use a sample voltage VS to a wafer (7) for adjusting a selected landing energy EL of primary charged particles within a large range of landing energies between 100 eV and 2 keV; and
   a detection unit (100) configured for imaging secondary electrons on an image sensor (600), the detection unit (100) comprising a first magneto-dynamic lens (205.1), a second pair of magneto-dynamic lenses (262; 205.2, 205.3), and a first fast electrostatic lens element (211, 211.1) and a second mechanism (211.2, 293), wherein the first fast electrostatic lens element (211, 211.1) and the second mechanism (211.2, 293) are configured for a dynamic compensation of charging effects during use, depending on the selected landing energy EL, and within the large range of landing energies between 100 eV and 2 keV.
Clause 2: The system according to clause 1, wherein, during use, secondary electrons are generated at interaction volumes of the plurality of primary charged particle beamlets (3) with a wafer (7), and wherein the secondary electrons are accelerated to a high kinetic energy ES of up to 30 keV, and wherein the first fast electrostatic lens element (211, 211.1) is configured to generate a large electrostatic lens power for influencing the secondary electrons at high kinetic energy ES.
Clauses 3: The system according to clauses 1 or 2, wherein the first fast electrostatic lens element (211, 211.1) is placed between a first tube segment (151.2) and second tube segment (159) of a beam tube enclosing a secondary electron beam path (13).
Clause 4: The system according to any of the clauses 1 to 3, wherein the first fast electrostatic lens element (211, 211.1) comprises at least one electrode (1104.2, 1104.3) connected to a first, dynamic voltage supply unit (842), configured to provide during use a dynamic changing low voltage C of up to +/−200V to the at least one electrode (1104.2, 1104.3).
Clause 5: The system according to any of the clauses 1 to 4, wherein the first fast electrostatic lens element (211, 211.1) is arranged downstream of the first magneto-dynamic lens (205.1) between a first, low energy intermediate image position (252) and a second, high energy intermediate image position (254) of the secondary electron beamlets (9).
Clause 6: The system according to any of the clauses 1 to 5, wherein the first fast electrostatic lens element (211, 211.1) comprises five or more electrodes (1104.1, 1104.2, 1104.3, 1104.4, 1104.5) with at least two electrodes (1104.2, 1104.4) connected to a second, static voltage supply unit (844) configured for providing during use of a quasi-static high voltage V larger than 5 keV, larger than 8 keV or even larger than 10 keV to each of the two electrodes (1104.2, 1104.4).
Clause 7: The system according to any of the clauses 1 to 6, wherein the second mechanism is a second fast electrostatic lens element (211.2).
Clause 8: The system according to clause 7, wherein the first and second fast electrostatic lens elements (211, 211.1, 211.2) are arranged downstream of the first magneto-dynamic lens (205.1) between a first, low energy intermediate image position (252) and a second, high energy intermediate image position (254) of the secondary electron beamlets (9).
Clause 9: The system according to any of the clauses 1 to 6, wherein the second mechanism is a position actuator (293) configured for changing the axial position of the first fast electrostatic lens element (211, 211.1).
Clause 10: The system according to any of the clauses 1 to 5, wherein the second mechanism is formed as a hybrid lens (217) configured for forming during use a quasi-static magnetic lens field at an axial position of an isolated tube lens segment (119) between a first beam tube segment (151.1) and a second beam tube segment (159), wherein the tube lens segment (119) is connected to a first, dynamic voltage supply unit (842) configured for dynamically changing a lens power of the hybrid lens (217).
Clause 11: The system according to clause 10, wherein the hybrid lens (217) comprises a coil (207) and a yoke (209), configured for limiting the extension of the quasistatic magnetic field during use to the axial position of the isolated tube lens segment (119).
Clause 12: The system according to clauses 10, wherein the hybrid lens (217) is formed as one of the group of lenses consisting of the magneto-dynamic lens (205.1), and a magneto-dynamic lens (205.2, 205.3) of the second pair of magneto-dynamic lenses (262).
Clause 13: The system according to any of the clauses 1 to 12, further comprising a lateral or tilt manipulator (291a, 291b) configured for adjusting a lateral position or a tilt of a lens element (205, 211) of the detection unit (200).
Clause 14: A fast electrostatic lens element (211, 211.1, 211.2) for changing a lens power for an electron beam of high kinetic energy ES >20 keV, for example ES up to 30 keV, comprising
   at least a first electrode connected to a first, dynamic voltage supply unit (842) configured for providing during use a dynamically changing low voltage C below +/−500V, such as below +/−250V,
   at least a second electrode connected to a second, static voltage supply unit (844) configured for providing during use a quasi-static high voltage V <−5 kV, such as V <−8 kV or V ˜−10 kV.
Clause 15: The element according to clause 14, wherein the first and the second electrode are identical.
Clause 16: The element according to clause 14 or 15, wherein the first and second electrode are configured as an isolated tube lens segment (119) arranged between a first tube segment 151.2 and a second tube segment (159) of a beam tube.
Clause 17: The element according to clause 16, wherein the isolated tube lens segment (119) is arranged in an axial range of a yoke (209) of a magnetic lens with a coil (207), configured for generating a magnetic lens field in the isolated tube lens segment (119).
Clause 18: The element according to clause 14 or 15, wherein the first electrode is placed between the second electrode and a third electrode, the third electrode connected to the second, static voltage supply unit (844) configured for providing during use a quasi-static high voltage V <−5 kV, such as V <−8 kV or V ˜−10 kV.
Clause 19: The element according to any of the clauses 14 to 18, comprising five or more electrodes (1104.1, 1104.2, 1104.3, 1104.4, 1104.5) with at least two electrodes (1104.2, 1104.4) connected to a second, static voltage supply unit (844) configured for providing during use of a quasi-static high voltage V larger than 5 keV, larger than 8 keV or even larger than 10 keV to each of the two electrodes (1104.2, 1104.4).
Clause 20: A method of operating a multi-beam charged particle beam system (1), comprising the steps of
   selecting an imaging setting including selection of a landing energy EL of primary charged particles,
   adjusting a deceleration field (137) close to a wafer surface (25) and at least one lens power of at least one magneto-dynamic projection lens (205.1, 205.2, 205.3) of a detection unit (200) to the selected landing energy EL,
   starting a scanning image acquisition,
   monitoring a position of a plurality of focus points (15) of a plurality of secondary electron beamlets (9) during the scanning image acquisition,
   determining a change in the positions of the plurality of focus points (15),
   computing, from the change, a compensation signal for compensation of a charging effect,
   converting the compensation signal into at least one dynamically changing low voltage C,
   providing the at least one dynamically changing low voltage C to at least one electrode of a fast lens element (211, 211.1, 211.2, 217) of the detection unit (200).
Clause 21: The method according to clause 20, wherein the monitoring is performed at a frame rate of at least 30 frames per second, such as with more than 100 frames per second.
Clause 22: The method according to clauses 20 or 21, further comprising, during the step of adjusting, providing at least one high, quasi-static voltage V to at least one electrode of the fast lens element (211, 211.1, 211.2, 217) of the detection unit (200).
Clause 23: A fast hybrid lens element (217) for changing a lens power for an electron beam of high kinetic energy ES >20 keV, for example ES up to 30 keV, comprising
   at least coil (207) arranged within a yoke (209) configured for forming during use a quasi-static magnetic lens field at an axial position;
   an isolated tube lens segment (119), arranged between a first beam tube segment (151.1) and a second beam tube segment (159), and arranged at the axial position, where the quasi-static magnetic lens field is generated,
   a first, dynamic voltage supply unit (842) connected to the isolated tube lens segment (119) configured for providing during use a dynamically changing low voltage C below +/−500V, such as below +/−250V for dynamically changing a lens power of the hybrid lens (217).

The disclosure is however not limited to the embodiments or clauses described above. The embodiments or examples can be fully or partly combined with one another, and various modifications within the scope of any person of ordinary skill in the art are covered by the embodiments and examples of the disclosure.

A list of reference numbers is provided:
1 multi-beamlet charged-particle system
3 primary charged particle beamlets, or plurality of primary charged particle beamlets
5 primary charged particle beam spot
7 object or sample
9 secondary electron beamlet, forming the plurality of secondary electron beamlets
13 secondary electron beam path
15 secondary charged particle focus spot
25 surface of object or sample
67 first material composition
69 second material composition
100 object irradiation unit
101 object plane
102 objective lens
103 field lens
108 first beam cross over
110 collective multi-beam raster scanner
133 electrode
135 first electric field
137 second electric field
139 extraction field vector
141 interaction volume
143 scanning direction
147 virtual interaction volume
149 scanned surface segment
151 beam tube
153 Beam exit opening
155 third tube segment
159 second tube segment
161 coil
163 pole shoe
165 lower pole shoe segment
19 secondary electron trajectory
200 detection unit
203 axial direction
205 magneto-dynamic lens
207 lens coil
209 pole shoe of yoke
211 fast correction lenses
213 actuator
215 guide bearing
217 fast hybrid lens
219 tube lens segment
220 multi-pole corrector
222 second raster scanner
225 secondary electron image plane
230 monitoring system
232 high resolution sensor
235 imaging lens
237 beam divider mirror
250 projection system
252 Low energy intermediate image position
254 High energy intermediate image position
256 first cross or pupil over position
258 second cross over or pupil position
260 first pair of lenses
262 second group of lenses
264 pair of fast correction lenses
266 charge compensation mechanism
281 electron trajectories of axial point with correction
282 electron trajectories of axial point without correction
283 electron trajectory of field point with correction
284 electron trajectory of field point without correction
291 positioning actuator
293 mechanical actuator
300 charged-particle multi-beamlet generator
301 charged particle source
303 collimating lenses
304 filter plate
305 primary multi-beamlet-forming unit
306 multi-aperture plates
309 primary electron beam
321 intermediate image surface
331 first field lens
333 second field lens
400 beam splitter or divider unit
500 sample stage
503 Sample voltage supply
505 sample mounting platform
600 image sensor
602 electron to photon conversion unit
605 collection lens
611 zoom lens
623 detection element
800 control unit
810 imaging control module
820 sensor module
830 primary beam-path control module
840 secondary beam-path control module
842 first, dynamic voltage supply unit
844 second, static voltage supply unit
850 stage control module
860 scanning control unit
870 contrast control module
880 control operation processor
890 memory
1100 fast electrostatic lens element
1104 electrostatic lens electrodes
1105 Voltage adder
1110 kinetic energy of secondary electrons

1. A multi-beam charged particle beam system, comprising:
a charged-particle multi-beamlet generator configured to generate a plurality of primary charged particle beamlets;
an object irradiation unit comprising an objective lens configured to form a plurality of focus spots of the plurality of primary charged particle beamlets in an object plane in which a surface an object is disposed;
a voltage supply unit configured to provide a sample voltage to the object so that a landing energy of primary charged particles at the surface of the object is between 100 electron Volts (eV) and 2 kiloelectron Volts (keV);
a detection unit configured to image secondary electrons on an image sensor, the detection unit comprising a magneto-dynamic lens, a pair of magneto-dynamic lenses, a fast electrostatic lens element and a mechanism,
wherein the fast electrostatic lens element and the mechanism are configured to dynamically compensate charging effects depending on the landing energy of the primary charged particles at the surface of the object.

2. The system of claim 1, wherein:
the system is configured to generate secondary electrons at interaction volumes of the plurality of primary charged particle beamlets with the object;
the system is configured to accelerate the secondary electrons to a kinetic energy of up to 30 keV; and
the fast electrostatic lens element is configured to generate an electrostatic lens power to influence the secondary electrons.

3. The system of claim 1, further comprising a beam tube comprising first and second tube segments, wherein the beam tube encloses a portion of a beam path of the secondary electrons, and the fast electrostatic lens element is between the first and second tube segments.

4. The system of claim 1, wherein the fast electrostatic lens element comprises an electrode connected to a dynamic voltage supply unit configured to provide a dynamically changeable voltage of up to +/−200V to the electrode.

5. The system of claim 1, wherein the fast electrostatic lens element is downstream of the first magneto-dynamic lens between a first energy intermediate image position of the secondary electron beamlets and a second energy intermediate image position of the secondary electron beamlets, and the first energy being less than the second energy.

6. The system of claim 1, wherein:
the fast electrostatic lens element comprises five or more electrodes;
at least two electrodes of the five or more electrodes are connected to a further voltage supply unit;
the further voltage supply unit is configured to provide a quasi-static high voltage of more than 5 keV.

7. The system of claim 1, wherein fast electrostatic lens element comprises a first fast electrostatic lens element, and the mechanism comprises a fast electrostatic lens element.

8. The system of claim 1, wherein:
the first and second fast electrostatic lens elements are arranged downstream of the first magneto-dynamic lens between a first energy intermediate image position of the secondary electron beamlets and a second energy intermediate image position of the secondary electron beamlets; and
the first energy is less than the second energy.

9. The system of claim 1, wherein the mechanism comprises a position actuator configured to change an axial position of the fast electrostatic lens element.

10. The system of claim 1, further comprising:
a first beam tube segment;
a second beam tube segment;
an isolated tube segment between the first and second beam tube segments; and
a further voltage supply,
wherein:
the further voltage supply is connected to the isolated tube segment to dynamically change a lens power of the hybrid lens; and
the mechanism comprises a hybrid lens configured to form a quasi-static magnetic lens field at an axial position of the isolated tube lens segment.

11. The system of claim 10, wherein the hybrid lens comprises a coil and a yoke, and the hybrid lens is configured to limit an extension of the quasistatic magnetic field during to the axial position of the isolated tube lens segment.

12. The system of claim 10, wherein the hybrid lens comprises a member selected from the group consisting of: i) one of the group of lenses defining the magneto-dynamic lens; and ii) a magneto-dynamic lens of the second pair of magneto-dynamic lenses.

13. The system of claim 1, further comprising a manipulator configured to: i) adjust a lateral position of one of the lens elements of the detection unit; or ii) a tilt of one of the lens elements of the detection unit.

14. The system of claim 1, further comprising a beam divider configured to separate the secondary electrons from the plurality of primary charged particle beamlets.

15. A fast electrostatic lens element, comprising:
a first electrode;
a first voltage supply connected to the electrode so that the first voltage supply is configured to provide a dynamically changing voltage below +/−500 Volts (V);
a second electrode; and
a second voltage supply connected to the second electrode so that the second voltage supply is configured to provide a quasi-static high voltage of less than <−5 kilo Volts (kV),
wherein the fast electrostatic lens element is configured to change a lens power for an electron beam having a kinetic energy of at least 20 kiloelectron Volts.

16. The element of claim 15, wherein the first and the second electrodes are identical.

17. The element of claim 15, wherein the first and second electrodes are define an isolated tube lens segment between a first tube segment of a beam tube a second tube segment of the beam tube.

18. (canceled)

19. The element of claim 15, wherein the first electrode is between the second electrode and a third electrode, and the third electrode is connected to the second voltage supply unit to provide a quasi-static high voltage of at most-5 kV.

20. The element of claim 15, further comprising five or more electrodes, wherein at least two of the electrodes are connected to a further voltage supply unit configured to provide a quasi-static voltage of at least 5 keV.

21. A method of operating a multi-beam charged particle beam system, the method comprising:
selecting an imaging setting including selection of a landing energy of primary charged particles;
adjusting a deceleration field close to a wafer surface and at least one lens power of at least one magneto-dynamic projection lens of a detection unit to the selected landing energy;
starting a scanning image acquisition;
monitoring a position of a plurality of focus points of a plurality of secondary electron beamlets during the scanning image acquisition;
determining a change in the positions of the plurality of focus points;
computing, from the change, a compensation signal for compensation of a charging effect;
converting the compensation signal into at least one dynamically changing low voltage; and
providing the at least one dynamically changing low voltage to at least one electrode of a fast lens element of the detection unit.

22. (canceled)

23. (canceled)
